(19) United States
(12) Patent Application Publication
(10) Pub. No.: US 2009/0029523 A1
(43) Pub. Date: Jan. 29, 2009

(54) Method of Fabricating Flash Memory Device

(75) Inventors: Ji Hyun Seo, Kyeongki-do (KR); Seok Pyo Song, Seoul (KR); Dong Sun Sheen, Kyeongki-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 12/179,448

(22) Filed: Jul. 24, 2008

(30) Foreign Application Priority Data
Jul. 25, 2007 (KR) 10-2007-0074594
Sep. 5, 2007 (KR) 10-2007-0090001

(51) Int. Cl. H01L 21/762

(52) U.S. Cl. 438/425; 438/593; 257/E21.546

(57) ABSTRACT

The invention relates to a method of fabricating flash memory device. In accordance with an aspect of the invention, the method includes forming a gate insulating layer, a first conductive layer, and an isolation mask over a semiconductor substrate. The isolation mask is patterned to expose regions in which an isolation layer will be formed. The first conductive layer, the gate insulating layer, and the semiconductor substrate are etched using the patterned isolation mask to form trenches. A liner oxide layer is formed on the resulting structure including the trenches. The trenches in which the liner oxide layer is formed are filled with an insulating layer. A planarizing process and a cleaning process are carried out such that wing spacers covering the gate insulating layer are formed at top edge portions of the isolation layer, thereby forming the isolation layer.

### CROSS-REFERENCES TO RELATED APPLICATIONS

Priority to Korean Patent application Nos. 10-2007-0074594, filed on Jul. 25, 2007, and 10-2007-0090001, filed on Sep. 5, 2007, the disclosures of which are incorporated herein by reference in their entireties, is claimed.

### BACKGROUND OF THE INVENTION

1. Field of the Invention

The invention relates to a method of fabricating flash memory devices and, more particularly, to a method of fabricating a flash memory device, which can reduce an interference effect between floating gates.

2. Background of Related Technology

As the line width of a flash memory device decreases, it becomes more difficult to perform a filling process for forming the isolation layer, and an interference effect, which occurs between floating gates or a control gate and a channel, also becomes problematic. The interference effect occurs because the distance between conductors or a conductor and a channel is small. Therefore, the interference effect is a problem that inevitably occurs as the line width is narrowed.

Referring to FIG. 1, in the prior art method, a gate insulating layer 11 and a first conductive layer 12a for a floating gate are formed over a semiconductor substrate 10. A trench 13 is formed through a self-aligned shallow trench isolation (SA-STI) process. The trench 13 is filled with insulating material to thereby form an isolation layer 14. A second conductive layer 12b for the floating gate is formed over the isolation layer 14 and the first conductive layer 12a. The second conductive layer 12b is patterned to form a floating gate 12 in which the first conductive layer 12a and the second conductive layer 12b are stacked. A first oxide layer 15, a nitride layer 16 and a second oxide layer 17 are sequentially formed over the floating gate 12 and the isolation layer 14 to form a dielectric layer 18. A control gate 19 is formed on the dielectric layer 18.

In a NAND type flash memory device, for example, in which a part of the floating gate 12 and the isolation layer 14 are formed by employing the SA-STI process, the isolation layer is disposed between the first and second conductive layers 12a, 12b of the floating gates 12, resulting in the floating gate/the isolation layer/the floating gate structure. This structure serves as parasitic capacitance when the device is operated by generating an interference effect between the floating gates 12.

Referring to FIG. 2, the interference effect is proportional to the distance between adjacent elements of the floating gate and the height of the floating gate. In other words, the greater the distance between the floating gates, or the lower the height of the floating gate, the less the interference effect. However, as a result of the fabrication of devices having a smaller line width, the ability to increase the distance between the floating gates is limited. Further, the coupling ratio of the floating gate and the control gate, which is necessary for device operation, limits the ability to reduce the height of the floating gate.

### BRIEF SUMMARY OF THE INVENTION

The invention is directed to preventing an interference effect occurring between adjacent elements of the floating gates by forming a control gate between the floating gates.

In accordance with an aspect of the invention, a method of fabricating a flash memory device includes forming a gate insulating layer, a first conductive layer, and an isolation mask over a semiconductor substrate. The isolation mask is patterned to expose regions in which one or more isolation layers will be subsequently formed. The first conductive layer, the gate insulating layer, and the semiconductor substrate are etched using the patterned isolation mask as an etch mark, to form trenches. A liner oxide layer is formed on the resulting structure, including the trenches. The trenches, in which the liner oxide layer is formed, are filled with an insulating layer. A planarizing process and a cleaning process are performed to form the isolation layer. The planarizing and cleaning processes are performed such that wing spacers covering the gate insulating layer are formed at the top edge portions of the isolation layer.

A wall oxide layer can be formed on a structure including the trenches before the liner oxide layer is formed.

A second conductive layer can be formed over the isolation layer and the first conductive layer. The second conductive layer can be patterned to form a floating gate in which the first conductive layer and the second conductive layer are stacked. A dielectric layer can be formed on the floating gate and the isolation layer. A control gate can be formed on the dielectric layer.

In accordance with another aspect of the invention, a method of fabricating a flash memory device includes forming a gate insulating layer, a first conductive layer, and an isolation mask over a semiconductor substrate. The isolation mask is patterned to expose regions in which isolation layer will be subsequently formed. The first conductive layer, the gate insulating layer, and the semiconductor substrate are etched using an etch process employing the patterned isolation mask as an etch mark, to form first trenches. Spacers are formed on sidewalls of the first trenches. Exposed portions of the semiconductor substrate are etched using an etch process using the spacers and the isolation mask as an etch mask to form second trenches. The spacers are removed to form third trenches, each comprising the first and second trenches. The third trenches are filled with an insulating layer having seams. The insulating layer is etched to form the isolation layer comprising the insulating layer. The insulating layer is etched such that wing spacers covering the gate insulating layer are formed at top edge portions of the isolation layer.

Before the insulating layer is formed in the third trenches, a wall oxide layer can be formed on a structure, including the third trenches, using, for example, a TEOS layer or a thermal oxide layer.

After etching the insulating layer, a passivation layer can be formed to fill holes in which top end portions of the isolation layer constitute a bottom. A planarizing process can be carried out to expose a top end of the isolation mask, thereby making the passivation layer remained within the holes. The isolation mask can be removed by an etch process using the passivation layer as an etch mask. The passivation layer can then be removed.

A second conductive layer can be formed over the isolation layer and the first conductive layer. The second conductive layer can be patterned to form a floating gate in which the first conductive layer and the second conductive layer are stacked. A dielectric layer can be formed on the floating gate and the isolation layer. A control gate can be formed on the dielectric layer.

In accordance with still another aspect of the invention, a method of fabricating a flash memory device includes forming a gate insulating layer, a first conductive layer, and an isolation mask over a semiconductor substrate. The isolation mask is patterned to expose regions in which isolation layer will be subsequently formed. The first conductive layer, the gate insulating layer, and the semiconductor substrate are etched using the patterned isolation mask as an etch mark to form first trenches. Spacers are formed on sidewalls of the first trenches. Exposed portions of the semiconductor substrate are etched by an etch process using the spacers and the isolation mask as an etch mask to form second trenches. The spacers are removed to form third trenches, each comprising the first and second trenches. A wall oxide layer is formed on the resulting structure, including the third trenches. The third trenches in which the wall oxide layer is formed are filled with an insulating layer. A planarizing process is performed to expose a top end of the isolation mask. The isolation mask is removed. A planarizing process and a cleaning process are performed to form the isolation layer. The planarizing and cleaning processes are performed such that wing spacers covering the gate insulating layer are formed at top edge portions of the isolation layer.

After the isolation layer is formed, a second conductive layer can be formed over the isolation layer and the first conductive layer. The second conductive layer can be patterned to form a floating gate in which the first conductive layer and the second conductive layer are stacked. A dielectric layer can be formed on the floating gate and the isolation layer, and a control gate can be formed on the dielectric layer.

### BRIEF DESCRIPTION OF THE DRAWINGS

FIG. 1 is a sectional view illustrating a prior art method of fabricating a flash memory device;

FIG. 2 is a graph showing the relationship between the interference coupling ratio and both the height of a floating gate of a flash memory device and a distance between adjacent floating gates.

FIGS. 3 to 5, FIGS. 6A to 6C, and FIG. 7 are sectional views showing a method of fabricating a flash memory device in accordance with a first embodiment of the invention;

FIGS. 8 to 17 are sectional views showing a method of fabricating a flash memory device in accordance with a second embodiment of the invention; and

FIGS. 18 to 21 are sectional views showing a method of fabricating a flash memory device in accordance with a third embodiment of the present invention.

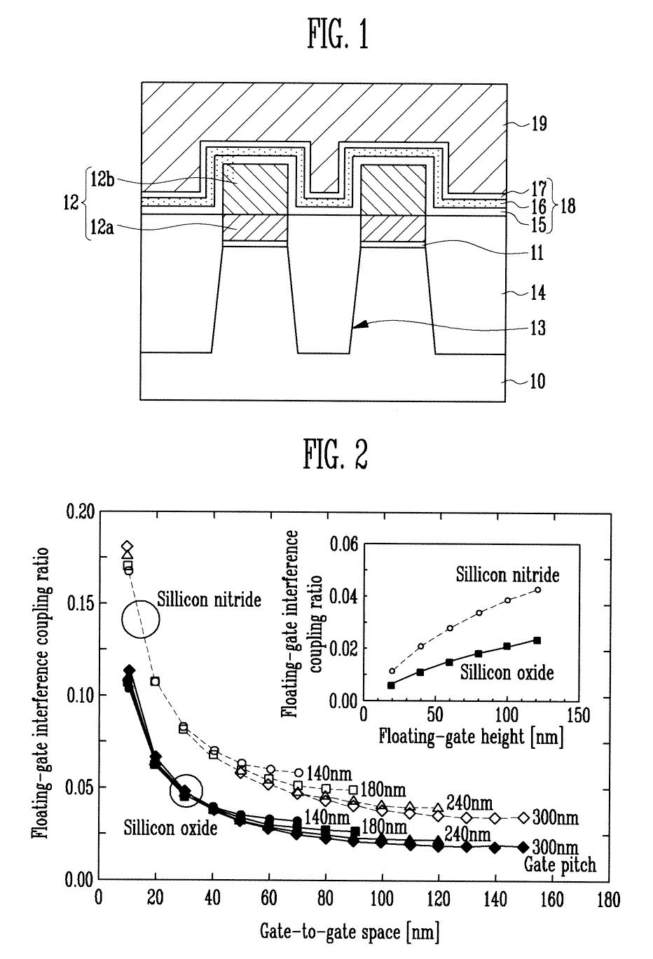

### DESCRIPTION OF SPECIFIC EMBODIMENTS

Specific embodiments according to the invention will be described with reference to the accompanying drawings. However, the invention is not limited to the disclosed embodiments, but may be implemented in various ways. The embodiments are provided to complete the disclosure of the invention and to allow those having ordinary skill in the art to understand the scope of the invention. The invention is defined by the category of the claims.

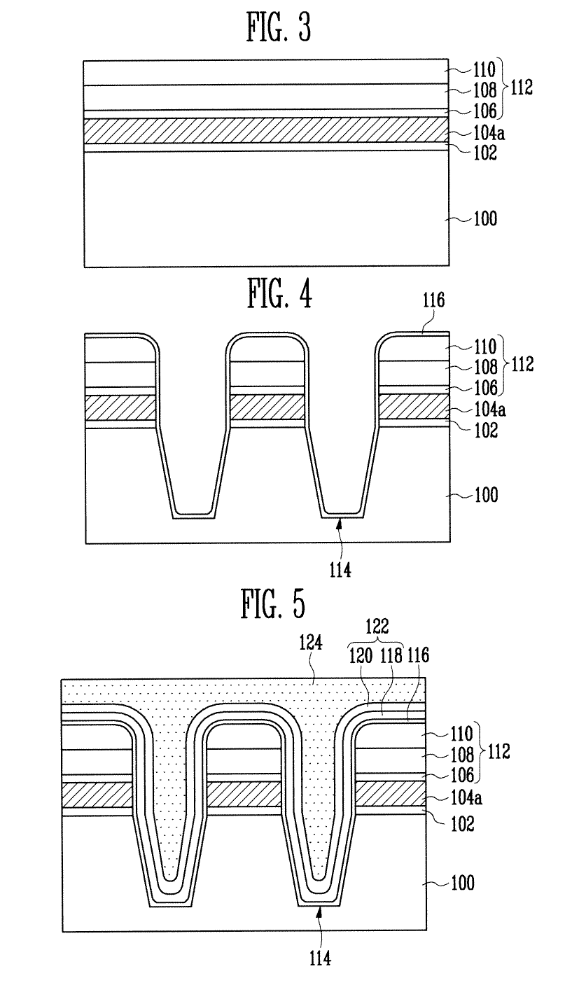

Referring to FIG. 3, a gate insulating layer 102, a first conductive layer 104a for a floating gate, and an isolation mask 112 are sequentially formed over a semiconductor substrate 100.

The isolation mask 112 can have a stacked structure of a buffer oxide layer 106, a nitride layer 108, and a hard mask 110. The hard mask 110 can be formed from a nitride, an oxide material, SiON, or an amorphous carbon.

The first conductive layer 104a can be formed from polysilicon or any other material capable of storing electrons.

Referring to FIG. 4, the isolation mask 112 is patterned using, for example, a photolithography process to expose regions where the isolation layer will be subsequently formed. The first conductive layer 104a and the gate insulating layer 102 are sequentially etched using the patterned isolation mask 112 as an etch mark. The semiconductor substrate 100 is then etched to thereby form trenches 114. A wall oxide layer 116 is formed on the entire surface of the resulting structure, including the trenches 114.

The wall oxide layer 116 mitigates etch damage during the etch process for forming the trenches 114. The wall oxide layer 116 can be formed using, for example, a thermal oxidation process in a temperature, for example, in a range of 700 to 1000 degrees Celsius to prevent recrystalization of the first conductive layer 104a. The wall oxide layer 116 can be formed, for example, to a thickness in a range of 10 to 50 angstrom.

Alternatively, the formation process of the wall oxide layer 116 can be omitted, and instead the following processes can be performed.

Referring to FIG. 5, a liner oxide layer 122 is formed on the entire surface of the resulting structure including the wall oxide layer 116.

The trenches 114 are then filled with an insulating layer 124. The liner oxide layer 122 can be formed, for example, as a single layer, or the liner oxide layer 122 can have multiple layers. In the embodiment shown in FIG. 5, the liner oxide layer 122 has a two-layered structure of a first liner oxide layer 118 and a second liner oxide layer 120.

Each of the first liner oxide layer 118 and the second liner oxide layer 120 can be formed, for example, to a thickness in a range of 20 to 100 angstrom. Each of the first liner oxide layer 118 and the second liner oxide layer 120 can be formed, for example, by atomic layer deposition (ALD), low pressure chemical vapor deposition (LPCVD), an O₃-TEOS process, a high density plasma (HDP) process, a thermal oxidation process, or any combination thereof. In one embodiment, the thermal oxidation process can be performed using a method of forming a silicon layer or a silicon nitride layer, and then oxidizing the silicon layer or the silicon nitride layer. The first liner oxide layer 118 can be formed, for example, by forming the silicon layer or the silicon nitride layer on the wall oxide layer 116, and then performing, for example, a thermal oxidation process. The second liner oxide layer 120 can be formed, for example, by forming the silicon layer or the silicon nitride layer on the first liner oxide layer 118 and then performing, for example, a thermal oxidation process.

The first liner oxide layer 118 and the second liner oxide layer 120 can be formed to have the same etch rate when using the same etch process, or they can be formed to have different etch rates when using different processes. For example, when the etch rate of the first liner oxide 118 formed from a thermal oxide layer is 1, the etch rate of a second liner oxide layer 120 formed from HDP layer can be in a range of 1.5 to 3, the etch rate of a HTO layer can be in a range of 3 to 5, the etch rate of a LP-TEOS layer can be in a range of 5 to 10, and the etch rate of an O₃-TEOS layer can be in a range of 4 to 8.

The insulating layer 124 can be formed from a porous oxide material, such as a spin on glass oxide. The insulating layer 124 is formed to be etched faster than the liner oxide layer 122.

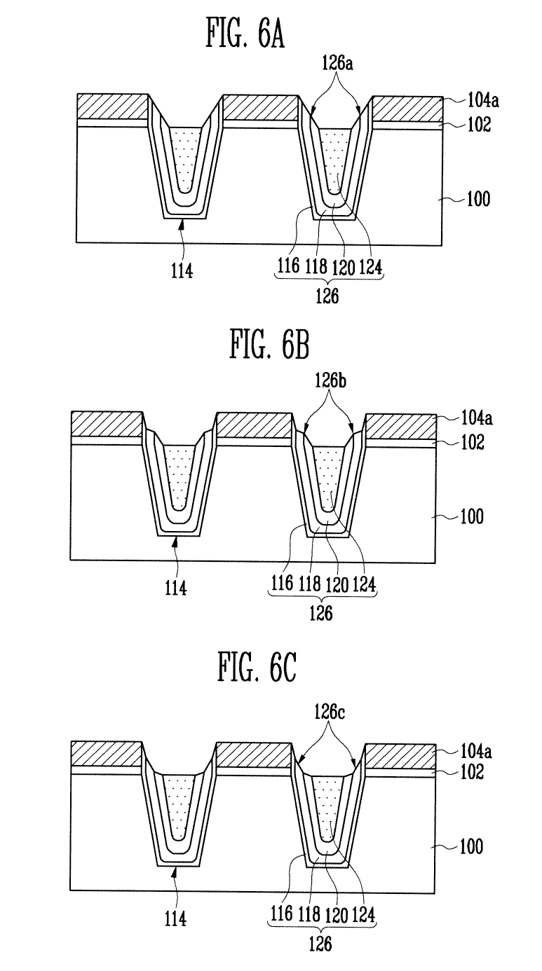

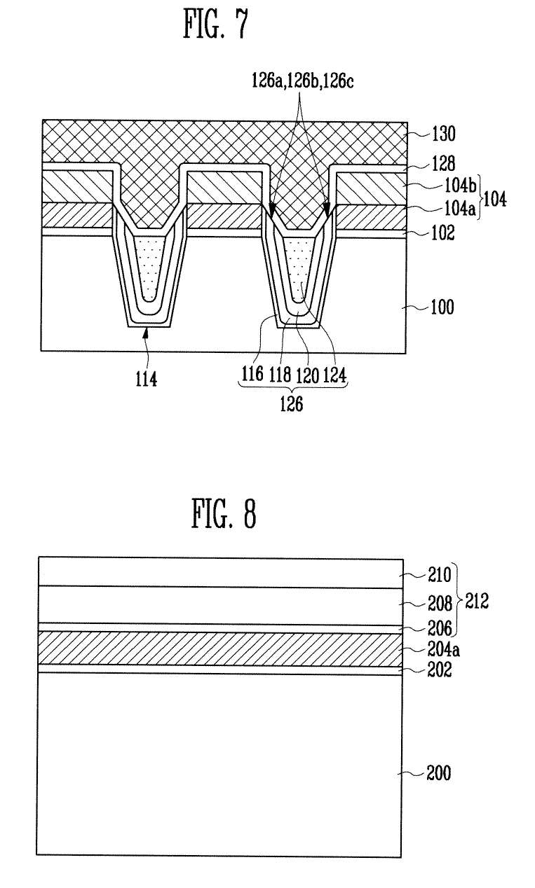

In the embodiment of FIG. 6A, the first liner oxide layer 118 and the second liner oxide layer 120 are formed to be etched equally fast. In the embodiment of FIGS. 6B and 6C, the first liner oxide layer 118 and the second liner oxide layer 120 are formed to be etched with different speed.

Referring to FIG. 6A, a planarizing process and a cleaning process are performed such that the wall oxide layer 116, the first liner oxide layer 118, the second liner oxide layer 120, and the insulating layer 124 remain within the trenches 114, to form forming an isolation layer 126.

The planarizing process can be performed, for example, until a top end of the first conductive layer 104a for the floating gate is exposed, or until the buffer oxide layer 106 is exposed. When the planarizing process is performed until the buffer oxide layer 106 is exposed, the buffer oxide layer 106 is removed during the cleaning process. A nitride layer strip process using, for example, phosphoric acid is preferably performed to fully remove residues of the nitride layer 108 after the planarizing process.

The cleaning process can be performed, for example, by controlling an etch target to become an effective field height (EFH) of the isolation layer 126, which is set in the design rule.

To control the EFH of the isolation layer 126, top ends of the isolation layer 126 are removed using, for example, a wet cleaning process using HF solution or BOE solution. A HF solution in which pure water is diluted at a ratio in a range of 100:1 or 500:1 or a BOE solution in which pure water is diluted at a ratio in a range of 300:1 can be used. The diluted ratio of the HF solution or the BOE solution, and pure water may be adjusted to control the etch rate.

Alternatively, to minutely control the EFH of the isolation layer 126, a dry cleaning process can be further performed.

In the dry cleaning process, the wall oxide layer 116, the liner oxide layer 122, and the insulating layer 124 have different etch amounts due to different etch rates. The first liner oxide layer 118 and the second liner oxide layer 120, constituting the liner oxide layer 122, are formed to be etched equally fast. As described above, the wall oxide layer 116 can be formed of thermal oxide material having a low etch rate through the thermal oxidation process. The liner oxide layer 122 can be formed to be etched as equally fast as or faster than the wall oxide layer 116. The insulating layer 124 can be formed to be etched faster the liner oxide layer 122. The insulating layer 124 is formed of oxide material. Accordingly, wing spacers 126a, each having a slope that is approximately equivalent to the slope of a straight line, are formed at top edge portions of the isolation layer 126. The wing spacers 126a are placed at the gate insulating layer 102, and function to protect the gate insulating layer 102. In order to improve the function of protecting the gate insulating layer 102, the angle of the wing spacer 126a can be in a range of 30 to 60 degrees.

Referring to FIG. 6B, in the process described with reference to FIG. 5, the first liner oxide layer 118 is etched faster than the second liner oxide layer 120, and the isolation layer 126 are formed by the planarizing process and the cleaning process. The planarizing process and the cleaning process are formed in the same manner as that described with reference to FIG. 6A. The etch rate of the layers increases in order of the wall oxide layer 116, the second liner oxide layer 120, the first liner oxide layer 118, and the insulating layer 124. Accordingly, the wing spacers 126b, each having a convex shape, are formed at top edge portions of the isolation layer 126. The convex shape of the wing spacers 126b improves the protection function of the wing spacers 126b as compared to the wing spacers 126a shown in FIG. 6A.

Referring to FIG. 6C, in the process described with reference to FIG. 5, the first liner oxide layer 118 is formed to be etched slower than the second liner oxide layer 120. The isolation layer 126 is formed by the above-described planarizing and cleaning processes. The planarizing and cleaning processes are performed in the same manner as described above, with reference to FIG. 6A. The etch rate of the layers increases in order of the wall oxide layer 116, the first liner oxide layer 118, the second liner oxide layer 120, and the insulating layer 124. Accordingly, wing spacers 126c, each having a concave shape, are formed at top edge portions of the isolation layer 126. The protection function of the wing spacers 126c is less than that of the wing spacers 126a shown in FIG. 6A, but wing spacers 126c can distribute an electric field affecting the gate insulating layer 102, and therefore improve the electrical properties.

The following Table 1 lists the etch rates of the liner oxide layer 122 and the insulating layer 124 in the cleaning process when the etch rate of the wall oxide layer 116, formed by the thermal oxidation process, is 1.

TABLE 1

| | Cleaning process | |
|---|---|---|
| | using phosphoric | Dry cleaning |
| | acid, HF, BOE | process |
| Wall oxide layer | 1 | 1 |
| Liner oxide layer | 1.5 to 10 | 1 to 3 |
| Insulating layer | 5 to 20 | 0.6 to 6 |

From Table 1, it can be seen that the etch rate of the liner oxide layer 122 is higher than that of the wall oxide layer 116, and the etch rate of the insulating layer 124 is higher than that of the liner oxide layer 122. Accordingly, the wing spacers 126a, 126b, or 126c are formed at the top end portions of the isolation layer 126. In the wet cleaning process using phosphoric acid, HF, and BOE, the etch ratio of the wall oxide layer 116, the liner oxide layer 122, and the insulating layer 124 is limited to a range of 1:1.5 to 7:5 to 20. In the dry cleaning process, the etch ratio of the wall oxide layer 116, the liner oxide layer 122, and the insulating layer 124 is limited to a range of 1:0.6 to 1.5:0.6 to 4.

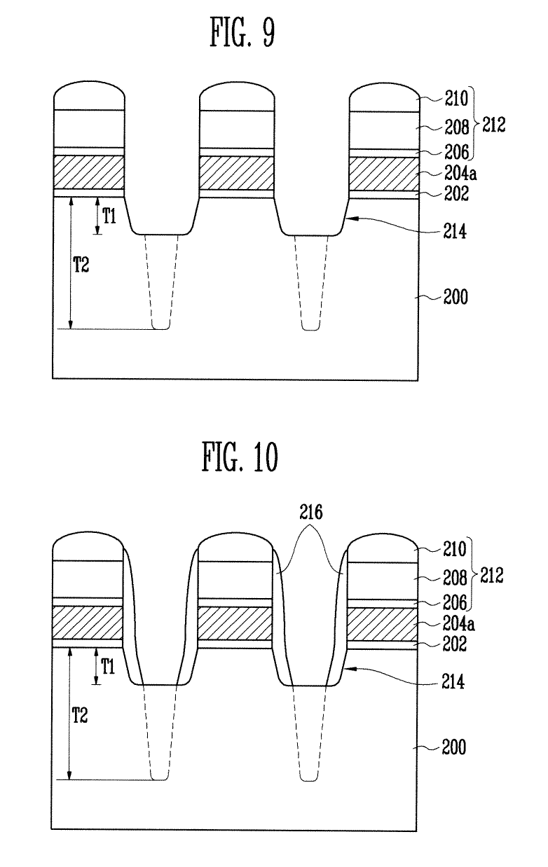

Referring to FIG. 7, a second conductive layer 104b for the floating gate is formed over the isolation layer 126, including the wing spacers 126a, 126b or 126c, and the first conductive layer 104a for the floating gate. The second conductive layer 104b is patterned to form a floating gate 104 in which the first conductive layer 104a and the second conductive layer 104b are stacked. A dielectric layer 128 is formed on the floating gate 104 and the isolation layer 126. A control gate 130 is formed on the dielectric layer 128. Further, the second conductive layer 104b for the floating gate can be formed, for example, of polysilicon or any other material that is capable of storing electrons.

FIGS. 8 to 17 are sectional views showing a method of fabricating a flash memory device in accordance with a second embodiment of the present invention.

Referring to FIG. 8, a gate insulating layer 202, a first conductive layer 204a for a floating gate, and an isolation mask 222 are sequentially formed over a semiconductor substrate 200.

The isolation mask 222 can have a stacked structure of a buffer oxide layer 206, a nitride layer 208, and a hard mask 220. The hard mask 220 can be formed, for example, of a nitride material, an oxide material, a SiON, or an amorphous carbon.

The first conductive layer 204a can be formed, for example, from polysilicon, or any other material capable of storing electrons.

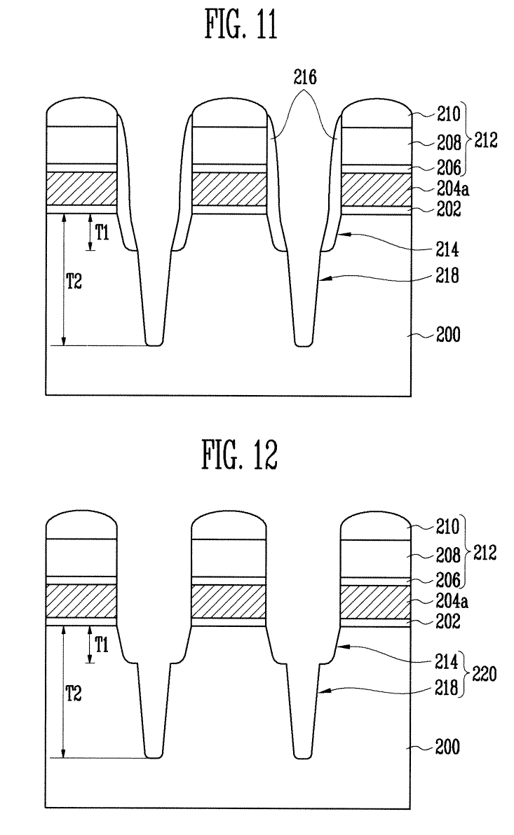

Referring to FIG. 9, the isolation mask 222 is patterned, using for example, a photolithography process, to expose regions where the isolation layer will subsequently be formed. The first conductive layer 204a and the gate insulating layer 202 are sequentially etched using the patterned isolation mask 222 as an etch mask. The semiconductor substrate 200 is then etched to form first trenches 214. While the first trenches 214 are formed, the hard mask 210 is also etched to a specific thickness.

Each of the first trenches 214 can have a depth T1, which is in a range of ⅙ to ⅓ of a depth T2 defined in the design rule. Meanwhile, a sidewall of the first trench 214 can be inclined at an angle in a range of 85 to 90 degrees.

Referring to FIG. 10, spacers 216 are formed on vertical inclined surfaces, including the sidewalls of the first trenches 214. The vertical inclined surfaces can include a sidewall of the isolation mask 212, a sidewall of the first conductive layer 204a for the floating gate, a sidewall of the gate insulating layer 202, and a sidewall of the first trench 214.

The spacer 216 can be formed by forming an insulating layer on the entire surface, including the first trenches 214, and then performing a blanket etchback process until a portion of the insulating layer at the bottom surface of the first trench 214 is removed. The insulating layer for forming the spacer 216 can be, for example, an oxide layer, a HTO layer, a nitride layer or a mixed layer thereof. The spacer 216 can be used as an etch mask in a subsequent etch process. Preferably the spacer 216 is formed of nitride materials, so that the spacer 216 can also function to prevent lateral oxidation of the first conductive layer 204a for the floating gate.

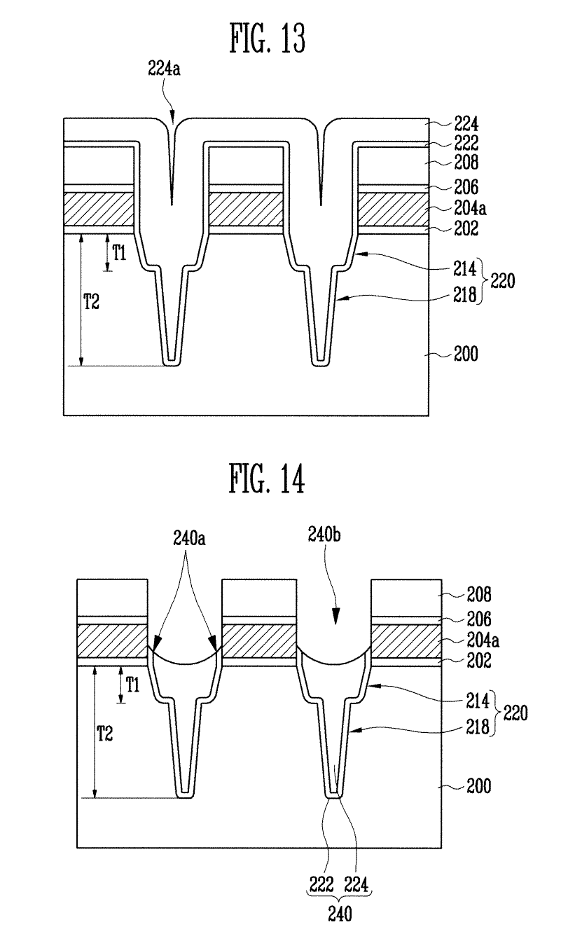

Referring to FIG. 11, exposed portions of the semiconductor substrate 200 are etched using the spacers 216 and the isolation mask 212 as an etch mask to form second trenches 218.

The second trenches 218 are formed by etching the semiconductor substrate 200 starting from a bottom surface of the first trench 214, until the second trench 218 has a depth T2 defined in the design rule.

Referring to FIG. 12, the spacers 216 are removed to form third trenches 220, each comprising the first and second trenches 214 and 218. The third trenches 220 have an upper width wider than a lower width.

The spacers 216 can be removed using, for example, fluoric acid solution when the spacers 216 are formed of oxide materials and phosphoric acid solution when the spacers 216 are formed of nitride materials. The spacers 216 can be only partially removed so that the remaining portion of the spacers 216 can prevent the sidewall of the first conductive layer 204a from being etched. Partial or full removal of the spacers 216 reduces the aspect ratio, thereby improving a fill characteristic of the third trenches 220.

Referring to FIG. 13, after the hard mask 210 is removed, an oxidation process is performed to form a wall oxide layer 222 on the entire surface, including the third trenches 220. An insulating layer 224 having excellent step coverage is formed of insulating material, and is formed on the wall oxide layer 222 so that seams 224a are generated while the third trenches 220 are filled with the insulating material. A thermal treatment process is then performed so as to improve the film quality of the insulating layer 124.

The wall oxide layer 222 functions to mitigate etch damage occurring during the trench etch process, and reduce the critical dimension (CD) of the active region. The wall oxide layer 222 can be formed, for example, from a TEOS oxide layer or a thermal oxide layer, and can be formed to a thickness in a range of 30 to 50 angstrom.

The insulating layer 124 can be formed of insulating material with excellent step coverage, such as a high aspect ratio process (HARP) insulating layer employing the HARP, or a SiO₂ layer. The insulating layer 224 has a poor filling characteristic since it is formed of insulating material with excellent step coverage. The seams 224a are thus formed at the middle portions of the third trenches 220.

The thermal treatment process can be performed using, for example, N₂ gas or H₂O gas, and in a temperature in a range of 800 to 1000 degrees Celsius. The thermal treatment process can be performed for a range of 30 minutes to 1 hour.

Referring to FIG. 14, the insulating layer 224 and the wall oxide layer 222 are etched to a predetermined thickness by controlling an etch target to become an EFH of the isolation layer, which is defined in the design rule. Accordingly, the isolation layer 240, each comprising the wall oxide layer 222 and the insulating layer 224, is formed in the third trenches 220, respectively.

The insulating layer 224 has the seam 240a at the middle portion of the third trench 220 and, therefore, the middle portion of the third trench 220 etches faster than other portions of the third trench 220. Consequently, wing spacers 240a, having a concave shape, are formed at top edge portions of the isolation layer 240. The wing spacers 240a cover the gate insulating layer 202, and therefore function to protect the gate insulating layer 202. Since the seams 240a exist in the insulating layer 224, the wing spacers 240a can be formed at the edge portions of the isolation layer 240, although the insulating layer 224 is etched by either a wet etch process or a dry etch process. Since the insulating layer 224 is etched at a predetermined thickness, holes 240b, each having a top end of the isolation layer 240 as a bottom, are formed.

Referring to FIG. 15, a passivation layer 226 is formed on the entire surface, including the isolation layer 240, so that the holes 240b are fully filled. A planarizing process is performed until a top end of the nitride layer 208 is exposed, so that the passivation layer 226 remains within the holes 240a.

The passivation layer 226 functions to protect the isolation layer 240 and also to safely remove the nitride layer 208 during a subsequent etch process. The passivation layer 226 can be formed, for example, of a PSZ layer or a HSQ layer. The passivation layer using a spin on glass (SOG) oxidation method. The material has a high etch selectivity for the isolation layer 240, but a low etch selectivity for the nitride layer 208 (that is, the isolation mask 212). For example, when the etch process is performed using FN solution (HF/H₂O+NH₄OH/H₂O₂/H₂O), the etch rate of an isolation layer 240 formed from a HARP insulating layer is 2 angstrom/sec, and the etch rate of a passivation layer 226 formed from a PSZ layer is 7 angstrom/sec.

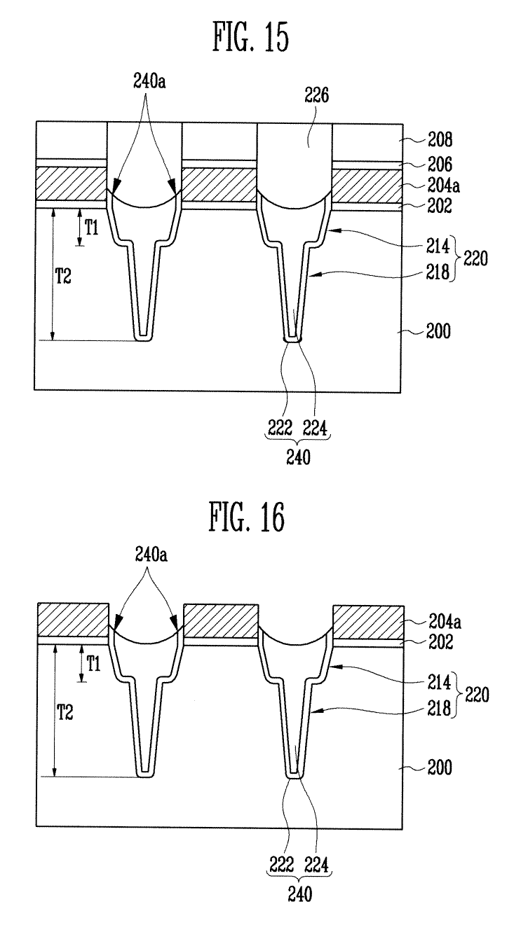

Referring to FIG. 16, the nitride layer 208 and the buffer oxide layer 206 are removed using an etch process using the passivation layer 226 as an etch mask. The passivation layer 226 can be removed, for example, by a wet etch process using, for example, FN solution or BFN solution (H₂SO₄/H₂O₂+HF/H₂O+NH₄OH/H₂O₂/H₂O).

Referring to FIG. 17, a second conductive layer 204b for the floating gate is formed on the isolation layer 240, having the wing spacers 240a, and the first conductive layer 204a for the floating gate. The second conductive layer 204b is patterned to form a floating gate 204, in which the first conductive layer 204a and the second conductive layer 204b are stacked. A dielectric layer 230 is formed over the floating gate 204 and the isolation layer 226. A control gate 232 is formed on the dielectric layer 228. The second conductive layer 204b for the floating gate can be formed of polysilicon or any other material that is able to store electrons.

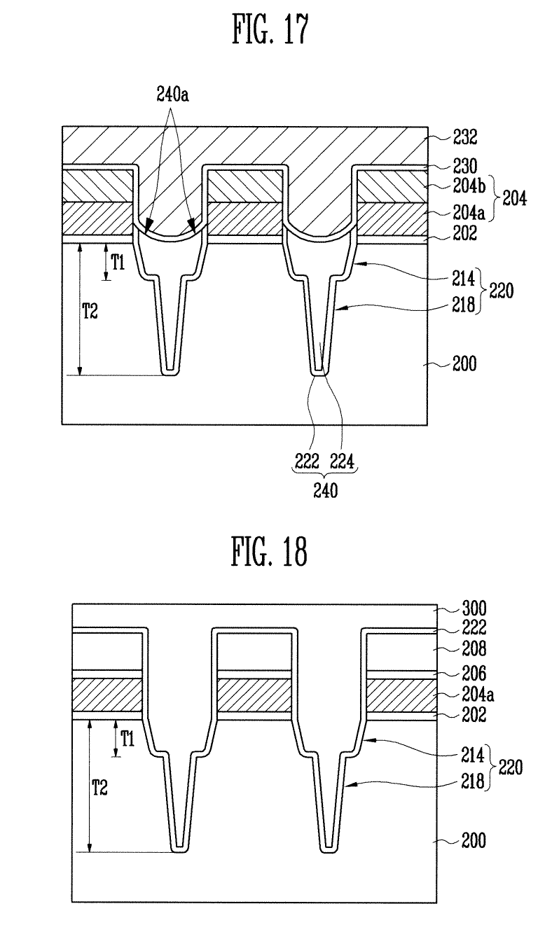

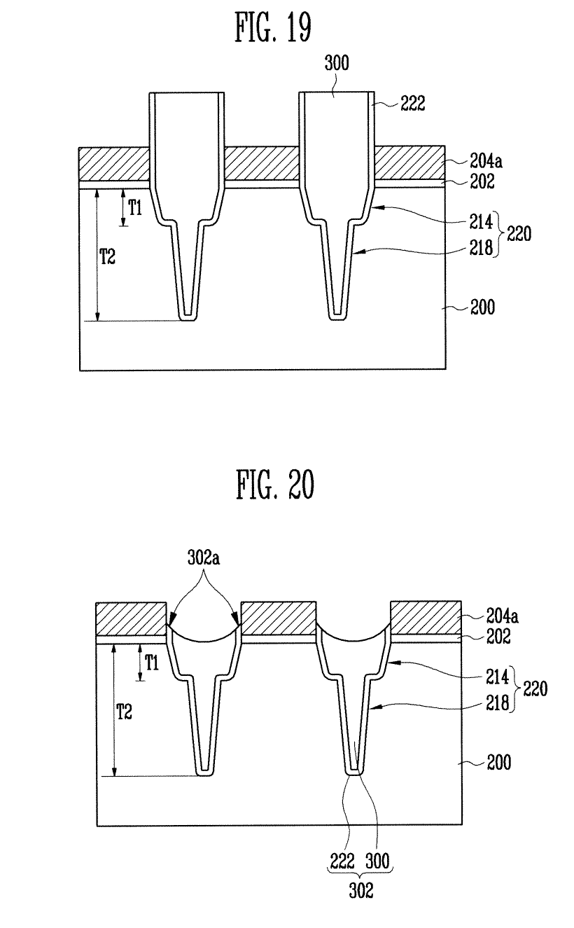

FIGS. 18 to 21 are sectional views showing a method of fabricating a flash memory device in accordance with a third embodiment of the invention.

A third embodiment of the invention is the same as the second embodiment described with reference to FIGS. 8 to 13 from the step of forming the gate insulating layer 202 on the semiconductor substrate 200 through the step of forming the wall oxide layer 222 on the entire surface including the third trenches 220.

Referring to FIG. 18, as described above with reference to FIG. 13, after a hard mask 210 is removed, an oxidation process is performed to form a wall oxide layer 222 on the entire surface, including third trenches 220. In order to fill the third trenches 220 with insulating material, an insulating layer 300, formed of insulating material having an excellent filling characteristic, is formed on the wall oxide layer 222. The insulating layer 300 can be formed, for example, from a PSZ layer.

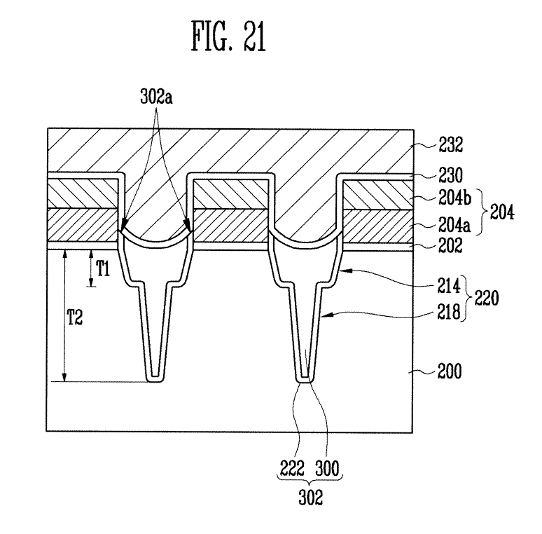

Referring to FIG. 19, a planarizing process is performed until the top end of a nitride layer 208 is exposed. The exposed nitride layer 208 is exposed, and a buffer oxide layer 206 is then removed.

Referring to FIG. 20, a cleaning process is performed to etch the wall oxide layer 222 and the insulating layer 300 to a predetermined thickness. Accordingly, an isolation layer 302, having the wall oxide layer 222 and the insulating layer 300, is formed in the third trenches 220.

The cleaning process is performed by controlling an etch target to become an EFH of the isolation layer 302, which is defined in the design rule. The cleaning process can be performed, for example, in a cleaning chamber using CF₄ and the CHF₃ as an etchant. Conditions for the cleaning chamber can include, for example, a pressure in a range of 50 mTorr to 200 mTorr, and can also include, for example, RF power in a range of 200 W to 400 W. In the etch process using CF₄ and CHF₃, the etch rate of a wall oxide layer 222 formed from a TEOS oxide layer is about 3.4 angstrom/sec, and the etch rate of the insulating layer 300 formed from a PSZ layer is about 3.8 angstrom/sec. Accordingly, the edge portions of the isolation layer 302 are etched slower than the middle portion of the isolation layer 302, so that wing spacers 302a are formed at top edge portions of the isolation layer 302. A surface of the isolation layer 302 having the wing spacers 302a is concaved in an elliptical shape having a horizontal diameter larger than a vertical diameter. The ratio of the horizontal diameter and the vertical diameter can range from about 10:7 to 1:1. The wing spacers 302a cover the gate insulating layer 202 and therefore function to protect the gate insulating layer 202.

Referring to FIG. 21, a second conductive layer 204b for a floating gate is formed over the isolation layer 302, having the wing spacers 302a, and the first conductive layer 204a for the floating gate. The second conductive layer 204b is patterned to form a floating gate 204 in which the first conductive layer 204a and the second conductive layer 204b are stacked. A dielectric layer 230 is formed on the floating gate 204 and the isolation layer 302. A control gate 232 is formed on the dielectric layer 228. Further, the second conductive layer 204b for the floating gate can be formed, for example, of polysilicon or any other material that is able to store electrons.

As described above, in accordance with the embodiments of the invention, the wing spacers covering the gate insulating layer are formed at the top edge portions of the isolation layer, and the control gate, not the isolation layer, is disposed between the floating gates. Consequently, a floating gate/isolation layer/floating gate structure (that is, a parasitic capacitance structure) is not formed. Accordingly, the invention can reduce an interference effect occurring between the floating gates, and can also protect the gate insulating layer. In the embodiments of the invention, a flash memory device has been described as an example. However, the invention can also be applied to semiconductor memory devices other than the flash memory device.

The embodiments disclosed herein have been proposed to allow a person skilled in the art to easily implement the invention, and the person skilled in the art may implement the invention by a combination of these embodiments. Therefore, the scope of the invention is not limited by or to the embodiments as described above, and should be construed to be defined only by the appended claims and their equivalents.

1. A method of fabricating a flash memory device, the method comprising:
forming a gate insulating layer and a first conductive layer over a semiconductor substrate;
etching the first conductive layer, the gate insulating layer, and the semiconductor substrate using an isolation mask pattern, to form trenches;
forming a liner oxide layer on the first conductive layer including the trenches;
filling the trenches, having the liner oxide layer formed thereon, with an insulating layer; and
forming an isolation layer using a planarizing process and a cleaning process,
wherein wing spacers covering the gate insulating layer are formed at top edge portions of the isolation layer, and a top of the isolation layer except for the wing spacers Is not higher than the gate insulating layer.

2. The method of claim 1, wherein the insulating layer is etched faster than the liner oxide layer in the cleaning process.

3. The method of claim 1, wherein the liner oxide layer comprises a layer selected from the group consisting of a thermal oxide layer, a HDP layer, a HTO layer, a LPTEOS layer, an O₃-TEOS layer, or at least two or more of them.

4. The method of claim 1, wherein:
the liner oxide layer comprises a stacked structure of a first liner oxide layer and a second liner oxide layer;
the first liner oxide layer is formed on the first conductive layer including the trenches; and,
the second liner oxide layer is formed on the first liner oxide layer.

5. The method of claim 4, wherein the first liner oxide layer and the second liner oxide layer are formed to be etched equally fast in the cleaning process when using the same process, or to be etched with different speed in the cleaning process when using different processes.

6. The method of claim 2, wherein the insulating layer is formed of a porous oxide material.

7. The method of claim 6, wherein the porous oxide material is a spin on glass oxide material.

8. The method of claim 2, wherein the cleaning process is performed using HF solution or BOE solution.

9. The method of claim 2, wherein the cleaning process is performed by controlling an etch target to become an effective field height (EFH) of the isolation layer.

10. The method of claim 1, further comprising forming a wall oxide layer on the first conductive layer including the trenches before the liner oxide layer is formed.

11. The method of claim 10, wherein the wall oxide layer is formed by a thermal oxidation process.

12. The method of claim 11, wherein, during the cleaning process, the insulating layer is etched faster than the liner oxide layer, and the liner oxide layer is etched as equally fast as or faster than the wall oxide layer.

13. The method of claim 1, further comprising:
forming a second conductive layer over the isolation layer and the first conductive layer;
patterning the second conductive layer to form a floating gate in which the first conductive layer and the second conductive layer are stacked; and
forming a dielectric layer and a control gate on the floating gate and the isolation layer.

14. A method of fabricating a flash memory device, the method comprising:
forming a gate insulating layer and a first conductive layer over a semiconductor substrate;
etching the first conductive layer, the gate insulating layer, and the semiconductor substrate using an isolation mask pattern to form first trenches;
forming spacers on sidewalls of the first trenches;
etching exposed portions of the semiconductor substrate using the spacers to form second trenches;
removing the spacers;
filling the first and the second trenches with an insulating layer having seams; and
forming an isolation layer using an etching process,
wherein wing spacers covering the gate insulating layer are formed at top edge portions of the isolation layer, and a top of the isolation layer except for the wing spacers is not higher than the gate insulating layer.

15. The method of claim 14, wherein each of the first trenches has a depth, which is in a range of ⅙ to ⅓ of a depth of the isolation layer.

16. The method of claim 14, wherein the spacers are formed of a layer selected from the group consisting of an oxide layer, a HTO layer, a nitride layer, and combination thereof.

17. The method of claim 14, further comprising, forming a wall oxide layer, formed of one of a TEOS layer or a thermal oxide layer, on the first conductive layer including the first and the second trenches before the insulating layer is formed.

18. The method of claim 14, wherein the insulating layer is formed using a high aspect ratio process (HARP) insulating layer or a SiO₂ layer.

19. The method of claim 14, wherein:
the insulating layer is etched using one of a wet etch process or a dry etch process; and,
the seams of the insulating layer are etched faster than other portions of the insulating layer, so that the wing spacers are formed at the top edge portions of the isolation layer.

20. The method of claim 14, further comprising:
forming a passivation layer to fill holes in which the top of the isolation layer constitute a bottom portion of the holes;
performing a planarizing process until a top end of the isolation mask is exposed, thereby making the passivation layer remain within the holes;
etching the isolation mask using the passivation layer as an etch mask to remove the isolation mask;
removing the passivation layer;
forming a second conductive layer over the isolation layer and the first conductive layer;
patterning the second conductive layer to form a floating gate in which the first conductive layer and the second conductive layer are stacked;
forming a dielectric layer on the floating gate and the isolation layer; and
forming a control gate on the dielectric layer after the isolation layer is formed.

21. The method of claim 20, wherein:
the passivation layer is formed of a PSZ layer or a HSQ layer and is formed using a SOG method,
the insulating layer is formed of a HARP insulating layer or a SiO₂ layer, and
the isolation mask pattern has a multi-layered structure including at least a nitride layer.

22. The method of claim 20, wherein the passivation layer is removed by a wet etch process using FN solution (HF/H₂O+NH₄OH/H₂O₂/H₂O) or BFN solution (H₂SO₄/H₂O₂+HF/H₂O+NH₄OH/H₂O₂/H₂O).

23. A method of fabricating a flash memory device, the method comprising:
forming a gate insulating layer and a first conductive layer over a semiconductor substrate;
etching the first conductive layer, the gate insulating layer, and the semiconductor substrate using an isolation mask pattern, to form first trenches;
forming spacers on sidewalls of the first trenches;
etching exposed portions of the semiconductor substrate using the spacers to form second trenches;
removing the spacers;
forming a wall oxide layer on the isolation mask pattern and the first conductive layer including the first and the second trenches;
filling the first and the second trenches, in which the wall oxide layer is formed with an insulating layer;
performing a planarizing process until a top end of the isolation mask pattern is exposed;
removing the isolation mask pattern; and
forming an isolation layer using a planarizing process and a cleaning process,
wherein wing spacers covering the gate insulating layer are formed at top edge portions of the isolation layer, and a top of the isolation layer except for the wing spacers is not higher than the gate insulating layer.

24. The method of claim 23, wherein each of the first trenches has a depth, which is in a range of ⅙ to ⅓ of a depth of the isolation layer.

25. The method of claim 23, wherein the spacers are formed of a layer selected from the group of an oxide layer, a HTO layer, a nitride layer, and combination thereof.

26. The method of claim 23, wherein the insulating layer is etched faster than the liner oxide layer in the cleaning process.

27. The method of claim 26, wherein:
the wall oxide layer is formed of a TEOS layer or a thermal oxide layer, and
the insulating layer is formed of a PSZ layer.

28. The method of claim 26, wherein:
the cleaning process is performed using CF₄ and CHF₃ in a cleaning chamber, and
conditions for the cleaning chamber include a pressure of 50 mTorr to 200 mTorr, and RF power of 200 W to 400 W.
